(19) United States
(12) Patent Application Publication
(10) Pub. No.: US 2023/0412172 A1
(43) Pub. Date: Dec. 21, 2023

(54) LEVEL-SHIFT CIRCUIT AND POWER SUPPLY

(71) Applicant: Rohm Co., Ltd., Kyoto (JP)

(72) Inventor: Kenichi OKAJIMA, Kyoto (JP)

(21) Appl. No.: 18/036,518

(22) PCT Filed: Nov. 10, 2021
(86) PCT No.: PCT/JP2021/041316

§ 371 Date: May 11, 2023

(30) Foreign Application Priority Data
Nov. 19, 2020 (JP) 2020-192707

(51) Int. Cl. H03K 19/0185; H03K 17/687; H02M 3/158; H02M 1/08

(52) U.S. Cl. CPC H03K 19/018521; H03K 17/687; H02M 3/158; H02M 1/08

(57) ABSTRACT

A level-shift circuit includes a first and a second input transistor configured to turn on and off complementarily according to a control signal, a first and a second switch configured, when on, to feed currents to the first and second input transistors respectively, a first and a second clamp element connected between the first and second input transistors and the first and second switches respectively, an output signal generator configured to generate an output signal resulting from level shifting of the control signal based on switching on and off of the currents supplied from the first and second switches to the first and second input transistors respectively, and a first and a second current regulator configured to regulate the current values of the currents flowing through the first and second switches, respectively, based on a first and a second feedback signal fed back from the output signal generator.

### TECHNICAL FIELD

The invention disclosed herein relates to a level-shift circuit and a power supply.

### BACKGROUND ART

In power supplies such as buck DC/DC converters, level-shift circuits are used to drive high-side transistors, in particular, N-channel MOSFETs. One example of related conventional art is seen in Patent Document 1 identified below.

### CITATION LIST

### Patent Literature

Patent Document 1: Japanese Unexamined Patent Application Publication No. 2019-134595

FIG. 1 is a circuit diagram of a conventional level-shift circuit. The level-shift circuit shown in FIG. 1 includes a first input transistor M1 and a second input transistor M2, a clamp element CLP1 and a clamp element CLP2, a transistor M3 and a transistor M4, a resistor R1 and a resistor R2, an output signal generator OG, a driver, and a capacitor C1. When the first input transistor M1 turns on, the resistor R1 reduces the current flowing through the first input transistor M1 during the transition of the gate voltage for the transistor M4 from high level to low level. When the second input transistor M2 turns on, the resistor R2 reduces the current flowing through the second input transistor M2 during the transition of the gate voltage for the transistor M3 from high level to low level. The clamp element CLP1 clamps the gate voltages for the transistor M4 and for a transistor M5, which will be described later, so that the gate voltages for the transistors M4 and M5 do not drop below a voltage VSW applied to a terminal SW. The clamp element CLP2 clamps the gate voltages for the transistor M3 and for a transistor M6, which will be described later, so that the gate voltages for the transistors M3 and M6 do not drop below the voltage VSW applied to the terminal SW. The first- and second input transistors M1 and M2 are N-channel MOSFETs and the transistors M3 and M4 are P-channel MOSFETs. Hereinafter, any transistor is an N-channel or P-channel MOSFET unless otherwise noted.

The output signal generator OG includes a transistor M5 and a transistor M6 constituting an input portion of the output signal generator OG, a transistor M7 and a transistor M8, a resistor R3 and a resistor R4, and an inverter INV2. When the transistor M5 turns on, the resistor R3 reduces the current flowing through the transistor M5 during the transition of the gate voltage for the transistor M8 from low level to high level. When the transistor M6 turns on, the resistor R4 reduces the current flowing through the transistor M6 during the transition of the gate voltage for the transistor M7 from low level to high level.

A control signal CTL is fed to the gate of the first input transistor M1. The inverter INV1 inverts the control signal CTL, and the inversion signal of the control signal CTL is fed from the inverter INV1 to the gate of the second input transistor M2. With this configuration, the first- and second input transistors M1 and M2 turn on and off complementarily. The capacitor C1 permits the voltage at a terminal BOOT to be kept equal to or higher than the control signal CTL and permits a high-side transistor (N-channel MOSFET) to be driven.

### SUMMARY OF INVENTION

### Technical Problem

FIG. 2 is a timing chart showing the voltages at relevant nodes in the level-shift circuit shown in FIG. 1. At time t1, the control signal CTL rises to turn from low level (ground level) to high level (supply voltage VIN). The control signal CTL is fed to the gate of the first input transistor M1, and the first input transistor M1, with its gate-source voltage open, turns on. As a result, the gate charge of the transistor M5 is discharged and the transistor M5 turns on. At this time, the inversion signal of the control signal CTL is fed to the gate of the second input transistor M2 and the second input transistor M2 turns off. Likewise, the transistor M6 turns off and the signal fed to the inverter INV2, that is, the signal resulting from level shifting of the control signal CTL turns to low level. As a result, the output signal of the inverter INV2, that is, a control signal CTL_LVS, turns to high level.

At time t2, the control signal CTL falls and turns from high level (supply voltage VIN) to low level (ground level). The inversion signal of the control signal CTL is fed to the gate of the second input transistor M2 via the inverter INV1, and the second input transistor M2, with its gate-source voltage open, turns on. As a result, the gate charge of the transistor M6 is discharged and the transistor M6 turns on. As a result, the output signal of the inverter INV2, that is, the control signal CTL_LVS, turns to low level. Thereafter, similar operation is repeated and the control signal CTL_LVS drives the high-side transistor via the driver. The control signal CTL_LVS shifts between the BOOT voltage and the SW voltage.

When the second input transistor M2 turns off at time t1, the drain-source voltage M2D of the second input transistor M2 is, for example, twice the supply voltage VIN. When the first input transistor M1 turns off at time t2, the drain-source voltage M1D of the first input transistor M1 is transiently, for example, twice the supply voltage VIN, and when the second input transistor M2 turns on, the drain-source voltage M2D of the second input transistor M2 is transiently, for example, twice the supply voltage VIN.

Thus, level shifting the control signal CTL requires an element having a withstand voltage sufficient to withstand at least the voltage level of the level-shifted signal. In general, a high-withstand voltage element requires a large area as well as an increased number of masks, and this leaves room for improvement in terms of manufacturing costs.

A configuration without a high-withstand voltage element may be considered, but that requires attention to be paid to avoid a large delay in the output signal of the level-shift circuit compared to the control signal.

### Solution to Problem

According to one aspect of what is disclosed herein, a level-shift circuit includes a first input transistor and a second input transistor configured to turn on and off complementarily according to a control signal, a first switch configured to feed a current to the first input transistor and a second switch configured to feed a current to the second input transistor, a first clamp element connected between the first input transistor and the first switch and a second clamp element connected between the second input transistor and the second switch, an output signal generator configured to generate an output signal resulting from level shifting of the control signal based on switching on and off of the currents supplied from the first and second switches to the first and second input transistors respectively, and a first current regulator configured to regulate the current value of the current flowing through the first switch based on a first feedback signal fed back from the output signal generator and a second current regulator configured to regulate the current value of the current flowing through the second switch based on a second feedback signal fed back from the output signal generator.

According to another aspect of what is disclosed herein, a power supply includes a level-shift circuit configured as described above.

### Advantageous Effects of Invention

According to the invention disclosed herein, it is possible to provide a level-shift circuit that achieves level shifting without a high-withstand voltage element and that can suppress a delay in the output signal of the level-shift circuit compared to a control signal.

### BRIEF DESCRIPTION OF DRAWINGS

FIG. 1 is a diagram showing a configuration example of a conventional level-shift circuit.

FIG. 2 is a timing chart in the conventional level-shift circuit.

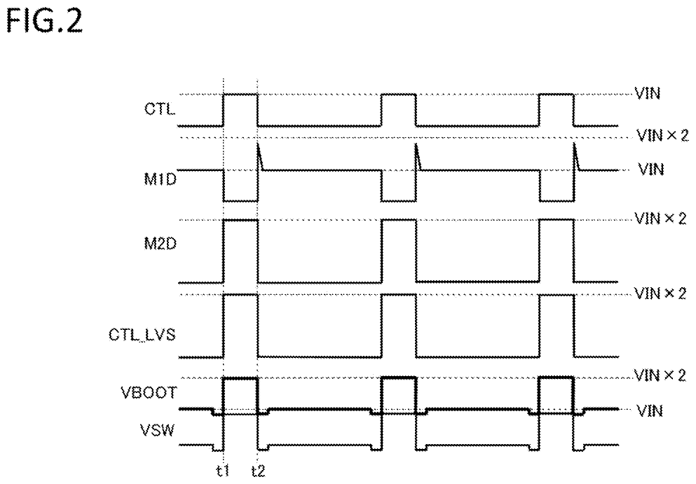

FIG. 3 is a diagram showing a configuration of a level-shift circuit according to a first embodiment.

FIG. 4 is a timing chart in the level-shift circuit according to the first embodiment.

FIG. 5 is a table showing the states of relevant elements in the level-shift circuit according to the first embodiment.

FIG. 6 is a diagram showing a configuration of a level-shift circuit according to a second embodiment.

FIG. 7 is a timing chart in the level-shift circuit according to the second embodiment.

FIG. 8 is a diagram showing an example of a power supply.

### DESCRIPTION OF EMBODIMENTS

### First Embodiment

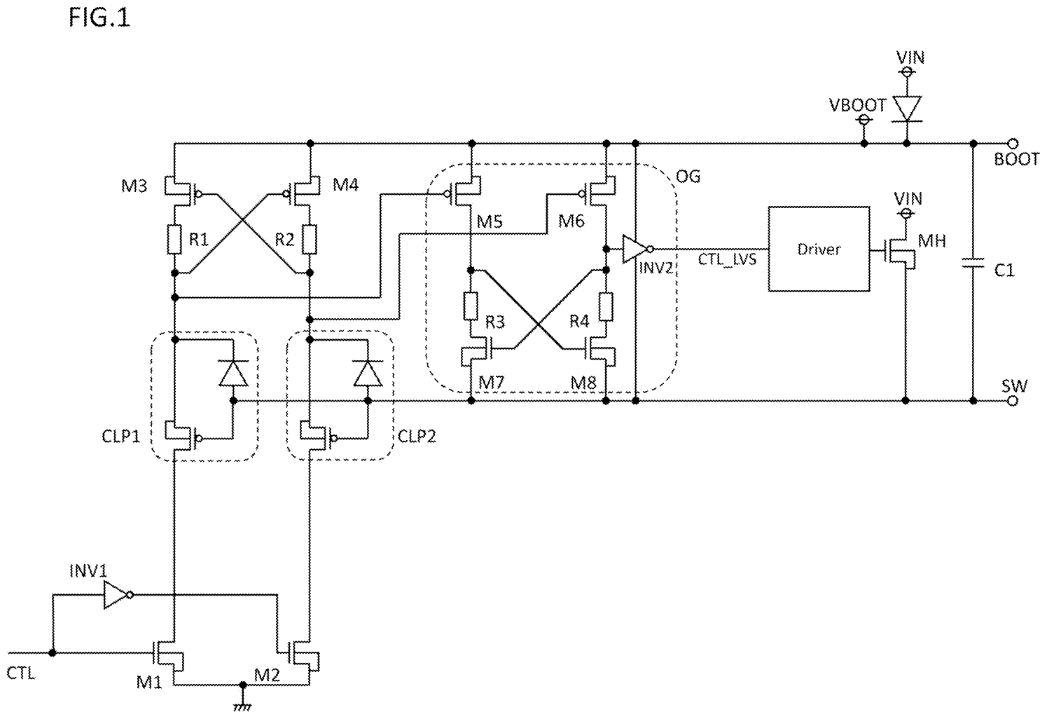

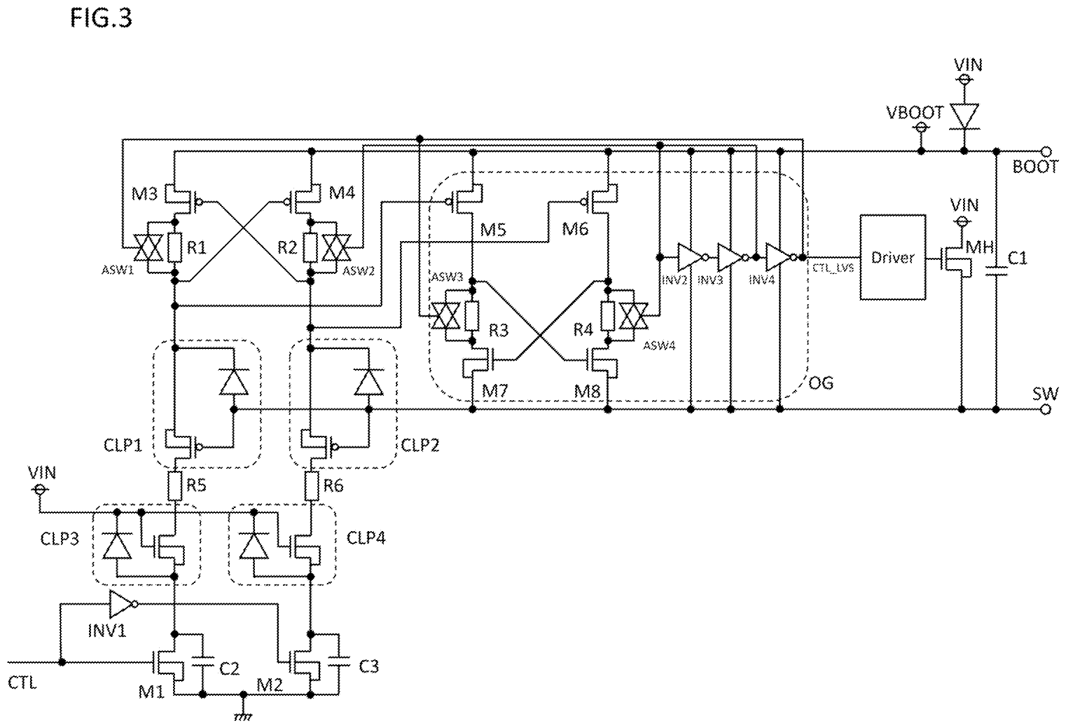

FIG. 3 is a diagram showing one configuration example of a level-shift circuit according to a first embodiment. The level-shift circuit shown in FIG. 1 includes, in addition to what is found in a conventional level-shift circuit, clamp elements CLP3 and CLP4, resistors R5 and R6, analog switches ASW1, ASW2, ASW3, and ASW4, capacitors C2 and C3, and inverters INV3 and INV4. For such parts as are found in the conventional circuit, no detailed description will be given.

The clamp elements CLP3 and CLP4 each include an N-channel MOSFET and a diode. The gate of the N-channel MOSFET is fed with a supply voltage VIN and is connected to the cathode of the diode. The drains of the N-channel MOSFETs in the clamp elements CLP3 and CLP4 are connected to one terminals of the resistors R5 and R6 respectively. The sources of the N-channel MOSFETs in the clamp elements CLP3 and CLP4 are connected to the drains of a first input transistor M1 and a second input transistor M2 respectively, and are also connected to the anodes of the diodes in the clamp elements CLP3 and CLP4 respectively. With this configuration, the drain-source voltages of the first and second input transistors M1 and M2 can be kept equal to or lower than the supply voltage VIN.

The resistor R5 is connected between the drain of the N-channel MOSFET in the clamp element CLP3 and the drain of the P-channel MOSFET in the clamp element CLP1 and the resistor R6 is connected between the drain of the N-channel MOSFET in the clamp element CLP4 and the drain of the P-channel MOSFET in the clamp element CLP2. The resistor R5 limits the current flowing through the transistor M3, which is one example of a first switch. The resistor R6 limits the current flowing through the transistor M4, which is one example of a second switch.

The analog switches ASW1, ASW2, ASW3, and ASW4 are connected in parallel with the resistors R1, R2, R3, and R4 respectively. In this embodiment, the analog switches ASW1 and ASW3 are turned on and off based on a first feedback signal and the analog switches ASW2 and ASW4 are turned on and off based on a second feedback signal. The output signal of the inverter INV4 is used as the first feedback signal just mentioned. The output signal of the inverter INV3 is used as the second feedback signal just mentioned.

By switching, with the analog switch ASW1, between the resistance value of the series-connected resistors R1 and R5 and the resistance value of the resistor R5 alone, it is possible to simultaneously achieve the function of the clamp element CLP1 and enhance the speed of level shifting of the gate voltage for the transistors M4 and M5. By switching, with the analog switch ASW2, between the resistance value of the series-connected resistors R2 and R6 and the resistance value of the resistor R6 alone, it is possible to simultaneously achieve the function of the clamp element CLP2 and enhance the speed of level shifting of the gate voltage for the transistors M3 and M6.

The capacitor C2 is connected between the drain and the source of the first input transistor M1. The capacitor C2 suppresses a transient rise of the drain-source voltage M1D of the first input transistor M1 due to the drain-source capacitance of the N-channel MOSFET in the clamp element CLP3. The capacitor C3 is connected between the drain and the source of the second input transistor M2. The capacitor C3 suppresses a transient rise of the drain-source voltage M2D of the second input transistor M2 due to the drain-source capacitance of the N-channel MOSFET in the clamp element CLP4.

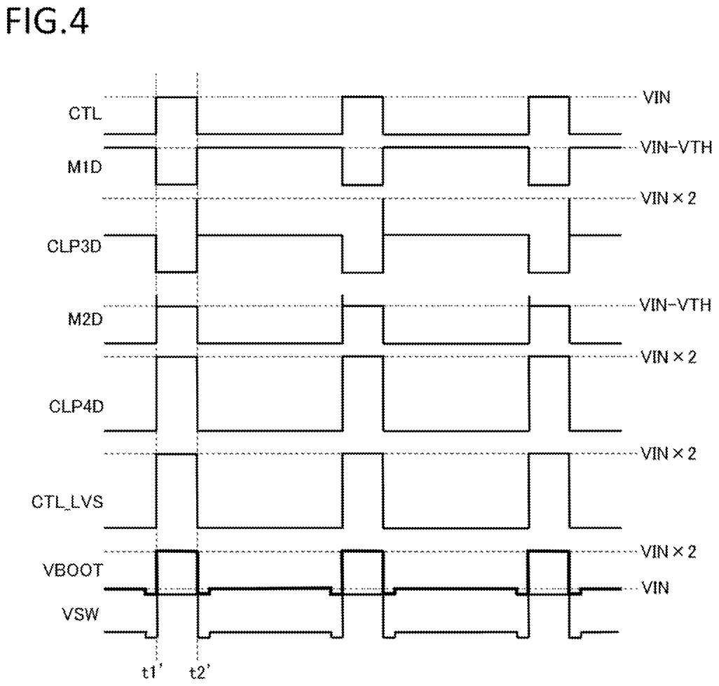

FIG. 4 is a timing chart showing the voltages at relevant nodes in the level-shift circuit shown in FIG. 3. At time t1′, the control signal CTL rises to turn from low level (ground level) to high level (supply voltage VIN), and the first input transistor M1, with its gate-source voltage open, turns on. At this time, the second input transistor M2 turns off and the drain-source voltage M2D of the second input transistor M2 rises to the clamp voltage of the clamp element CLP4. Thus, the withstand voltage of the second input transistor M2 can be as low as the supply voltage VIN.

At time t2′, the control signal CTL falls and the second input transistor M2 turns on. At this time, the first input transistor M1 turns off and the drain-source voltage M1D of the first input transistor M1 rises to the clamp voltage of the clamp element CLP3. Thus, the withstand voltage of the first input transistor M1 too can be as low as the supply voltage VIN. As will be understood from the above, there is no need to use high-withstand-voltage elements for the first and second input transistors. Also, for the N-channel MOSFETs in the clamp elements CLP3 and CLP4, since their drain-source voltages (CLP3D-M1D and CLP4D-M2D) are not higher than the supply voltage VIN, there is no need to use high-withstand-voltage elements.

The resistor R1 prevents a current exceeding the current capacity of the clamp elements CLP1 and CLP3 from flowing to the clamp elements CLP1 and CLP3 respectively. The resistor R1 also limits the current flowing through the first input transistor M1 to ensure that the transistor M4 turns on when the first input transistor M1 turns on. The resistor R2 prevents a current exceeding the current capacity of the clamp elements CLP2 and CLP4 from flowing to the clamp elements CLP2 and CLP4. The resistor R2 also limits the current flowing through the second input transistor M2 to ensure that the transistor M3 turns on when the second input transistor M2 turns on. Inconveniently, the resistors R1 and R2 causes a delay in level shifting. Thus, in this embodiment, the delay in level shifting is suppressed by providing the analog switches ASW1, ASW2, ASW3, and ASW4 as described above.

For example, when the first input transistor M1 turns on at t1′, the drain-source voltage MID of the first input transistor M1 falls from the clamp voltage to the ground level voltage. At this time, the first feedback signal fed back from the output signal generator OG turns off the analog switch ASW1 and the resistor R1 is not short-circuited across it; Thus, the transistor M4 turns on quickly. When the transistor M4 turns on, the first feedback signal turns on the analog switch ASW1.

By contrast, when the first input transistor M1 turns off at t2′, the drain-source voltage MID of the first input transistor M1 rises from the ground level voltage to the clamp voltage. At this time, the first feedback signal fed back from the output signal generator OG turns on the analog switch ASW1 and the resistor R1 is short-circuited across it; thus, the transistor M4 turns off quickly. When the transistor M4 turns off, the first feedback signal turns off the analog switch ASW1.

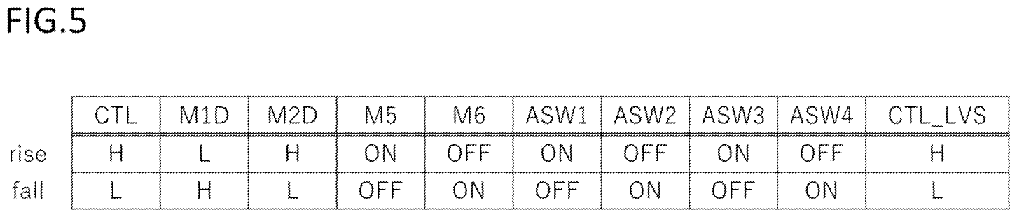

A similar description applies to the analog switches ASW2, ASW3, and ASW4: these are turned on and off with the first or second feedback signal fed back from the output signal generator OG to make the transistors M3, M8, and M7 turn on and off faster. See FIG. 5 for the state of each node and element when rising and falling.

### Second Embodiment

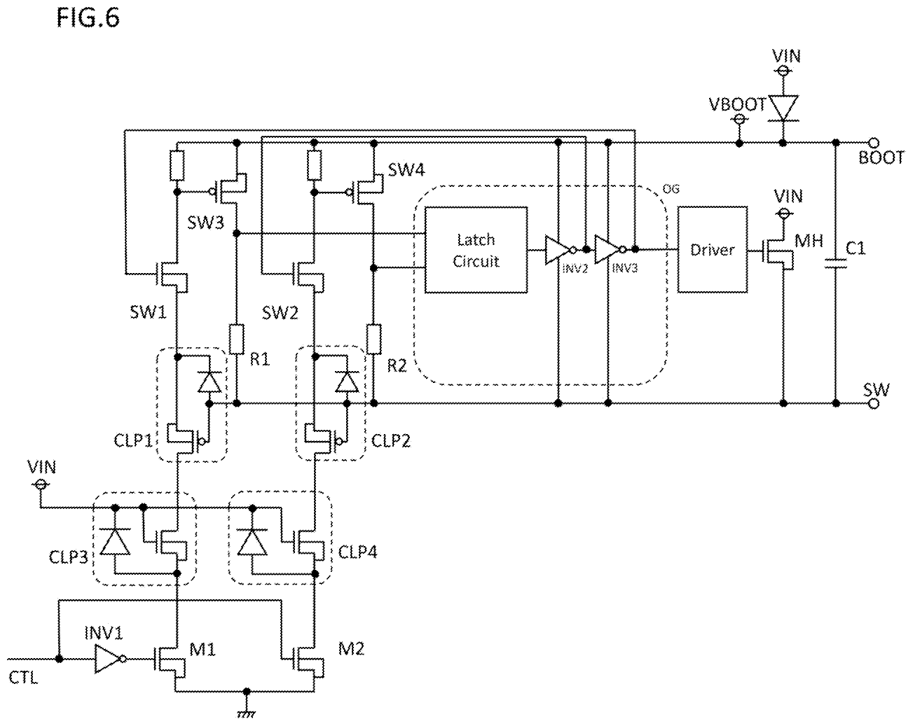

FIG. 6 is a diagram showing one configuration example of a level-shift circuit according to a second embodiment. The level-shift circuit shown in FIG. 6 includes first and second input transistors M1 and M2, clamp elements CLP1, CLP2, CLP3, and CLP4, a plurality of switch elements SW1, SW2, SW3, and SW4, resistors R1 and R2, an output signal generator OG, a driver, and a capacitor C1.

The output signal generator OG in the level-shift circuit shown in FIG. 6 includes a latch circuit and a plurality of inverters INV2 and INV3.

The inverter INV1 inverts a control signal CTL and the inversion signal of the control signal CTL is fed from the inverter INV1 to the gate of the first input transistor M1. The control signal CTL is fed to the gate of the second input transistor M2. The signal (output signal) fed from the INV3 is used as a first feedback signal and the signal fed from the INV2 is used as a second feedback signal.

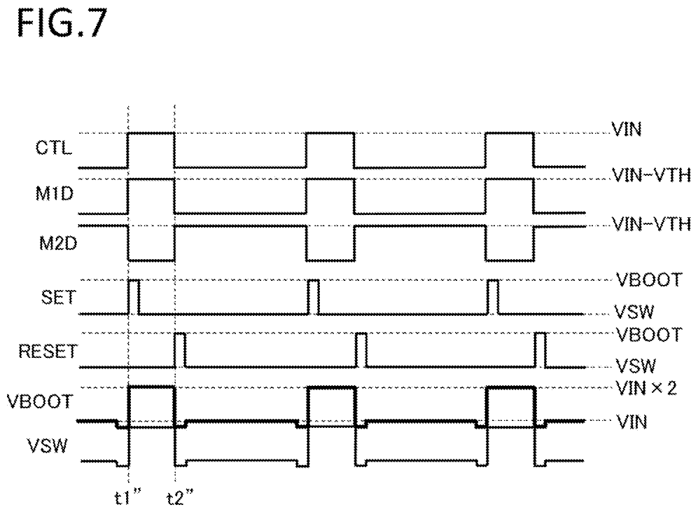

FIG. 7 is a timing chart showing the voltages at relevant nodes in the level-shift circuit shown in FIG. 6. At time t1″, the control signal CTL rises to turn from low level (ground level) to high level and the second input transistor M2, with its gate-source voltage open, turns on. At this time, the first feedback signal keeps the switch element SW2 on, and thus the switch element SW4, with its gate voltage turning to low level, turns on. As a result, a high-level set signal is fed to the latch circuit. When the high-level set signal is fed to the latch circuit, the first feedback signal turns off the switch element SW2 and the gate voltage for the switch element SW4 turns to high level; thus the switch element SW4 turns off. As a result, the level of the set signal fed to the latch circuit turns from high level to low level.

At time t2″, the control signal CTL falls and the first input transistor M1 turns on. At this time, the second feedback signal keeps the switch element SW1 on, and thus the switch element SW3, with its gate voltage turning to low level, turns on. As a result, a high-level reset signal is fed to the latch circuit. When the high-level reset signal is fed to the latch circuit, the second feedback signal turns off the switch element SW1 and the switch element SW3, with its gate voltage turning to high level, turns off. As a result, the level of the reset signal fed to the latch circuit turns from high level to low level. As in the level-shift circuit shown in FIG. 3, owing to the clamp elements CLP3 and CLP4, there is no need to use high-withstand-voltage elements for the first and second input transistors M1 and M2.

A major difference from the level-shift circuit shown in FIG. 3 is the presence of the latch circuit. The set signal rises at time t1″ and the reset signal rises at time t2″. The set and reset signals are fed to the latch circuit and the logic level of the signal fed to the INV2 is determined accordingly.

By switching on and off of the switch element SW2 with the first feedback signal and switching on and off the switch element SW1 with the second feedback signal, it is possible to generate set and reset signals, which are pulse signals, and to reduce current consumption. Although the configuration here differs from that of the level-shift circuit shown in FIG. 3, the two share a common feature of adjusting current during logic level shifting. Limiting current can also contribute to reducing power consumption.

<Application to a Power Supply>

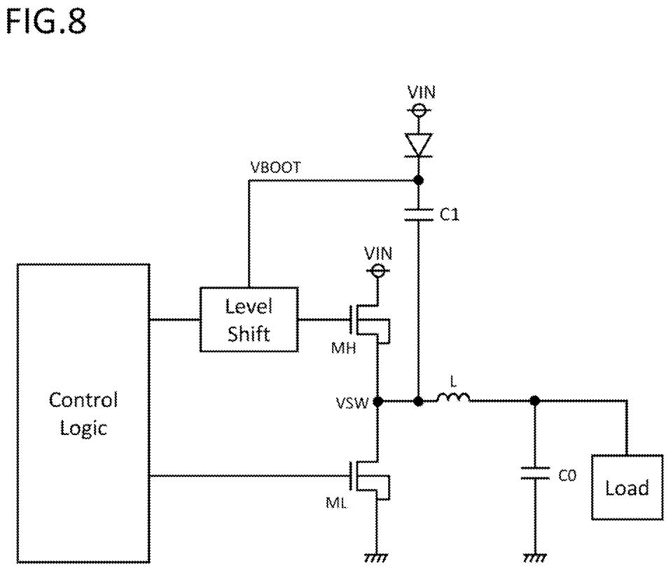

FIG. 8 is a diagram showing an example of a power supply. The power supply shown in FIG. 8 is a buck (step-down) DC/DC converter and includes a high-side transistor MH, a low-side transistor ML, an inductor L, an output capacitor CO, and a control logic portion. Its output voltage is fed to a load.

An N-channel MOSFET is used for the high-side transistor MH and a level-shift circuit is connected to its gate to allow switching operation. In this configuration, the level-shift circuits according to the embodiments described above are effective.

While the power supply shown in FIG. 8 is a buck DC/DC converter, this is not meant to limit the application of the level-shift circuit according to the embodiments described above; they are effective in any circuits that require level shifting of a signal, such as a boost (step-up) DC/DC converters and a switching devices.

### Other Modifications

The various technical features disclosed herein can be modified in various ways without departure from the spirit of the technical ingenuity. It should be understood that the above-described embodiment is in every aspect illustrative and not restrictive. The scope of the present invention is defined not by the description of the embodiment given above but by the appended claims, and encompasses any modifications made without departure from the scope and sense equivalent to those claims.

According to one aspect of what is disclosed herein, a level-shift circuit includes a first input transistor and a second input transistor configured to turn on and off complementarily according to a control signal, a first switch configured to feed a current to the first input transistor and a second switch configured to feed a current to the second input transistor, a first clamp element connected between the first input transistor and the first switch and a second clamp element connected between the second input transistor and the second switch, an output signal generator configured to generate an output signal resulting from level shifting of the control signal based on switching on and off of the currents supplied from the first and second switches to the first and second input transistors respectively, and a first current regulator configured to regulate the current value of the current flowing through the first switch based on a first feedback signal fed back from the output signal generator and a second current regulator configured to regulate the current value of the current flowing through the second switch based on a second feedback signal fed back from the output signal generator. (A first configuration.)

In the level-shift circuit of the first configuration described above, the first current regulator may include a first resistor that limits the current flowing through the first switch and the second current regulator may include a second resistor that limits the current flowing through the second switch. (A second configuration.)

In the level-shift circuit of the first or the second configuration described above, the first and second current regulators may each include an analog switch that turns on and off according to the first or second feedback signal. The current value may be regulated by the analog switch switching on and off. (A third configuration.)

In the level-shift circuit of any one of the first to third configuration described above, there may be further provided a third resistor connected between the first switch and the first clamp element, and a fourth resistor connected between the second switch and the second clamp element. (A fourth configuration.)

In the level-shift circuit of any one of the first to four configuration described above, there may be further provided a third clamp element connected between the first switch and the first clamp element and a fourth clamp element connected between the second switch and the second clamp element. (A fifth configuration.)

In the level-shift circuit of any one of the first to fifth configuration described above, there may be further provided a first capacitor connected in parallel with the first input transistor and a second capacitor connected in parallel with the second input transistor. (A sixth configuration.)

In the level-shift circuit of any one of the first to sixth configuration described above, the output signal generator may include a third switch and a fourth switch. (A seventh configuration.)

In the level-shift circuit of the seventh configuration described above, the output signal generator may further include a third current regulator configured to regulate the current value of the current flowing through the third switch based on the first feedback signal and a fourth current regulator configured to regulate the current value of the current flowing through the fourth switch based on the second feedback signal. (An eighth configuration.)

In the level-shift circuit of any one of the first to third configuration described above, the output signal generator may include a latch portion having a set terminal and a reset terminal to which a high-level or low-level signal is fed according to whether the first and second switches are on and off. (A ninth configuration.)

According to another aspect of what is disclosed herein, a power supply includes the level-shift circuit according to any one of the first to ninth configuration described above. (A tenth configuration.)

### REFERENCE SIGNS LIST

ASW1 to ASW4 analog switch
BOOT terminal
C1 to C3 capacitor
CLP1 first clamp element
CLP2 second clamp element
CLP3 third clamp element
CLP4 fourth clamp element
CO output capacitor
INV1 to INV4 inverter
L inductor
M1 first input transistor
M2 second input transistor
M3 to M8 transistor
MH high-side transistor
ML low-side transistor
OG output signal generator
R1 to R6 resistor
SW terminal
SW1 to SW4 switch element

1. A level-shift circuit comprising:
a first input transistor and a second input transistor configured to turn on and off complementarily according to a control signal;
a first switch configured to feed a current to the first input transistor and a second switch configured to feed a current to the second input transistor;
a first clamp element connected between the first input transistor and the first switch and a second clamp element connected between the second input transistor and the second switch;
an output signal generator configured to generate an output signal resulting from level shifting of the control signal based on switching on and off of the currents supplied from the first and second switches to the first and second input transistors respectively; and
a first current regulator configured to regulate a current value of a current flowing through the first switch based on a first feedback signal fed back from the output signal generator and a second current regulator configured to regulate a current value of a current flowing through the second switch based on a second feedback signal fed back from the output signal generator.

2. The level-shift circuit according to claim 1, wherein
the first current regulator includes a first resistor that limits the current flowing through the first switch; and
the second current regulator includes a second resistor that limits the current flowing through the second switch.

3. The level-shift circuit according to claim 1, wherein
the first and second current regulators each include an analog switch that turns on and off according to the first or second feedback signal; and
the current value is regulated by the analog switch switching on and off.

4. The level-shift circuit according to claim 1, further comprising:
a third resistor connected between the first switch and the first clamp element; and
a fourth resistor connected between the second switch and the second clamp element.

5. The level-shift circuit according to claim 1, further comprising:
a third clamp element connected between the first switch and the first clamp element; and
a fourth clamp element connected between the second switch and the second clamp element.

6. The level-shift circuit according to claim 1, further comprising:
a first capacitor connected in parallel with the first input transistor; and
a second capacitor connected in parallel with the second input transistor.

7. The level-shift circuit according to claim 1, wherein
the output signal generator includes a third switch and a fourth switch.

8. The level-shift circuit according to claim 7, further comprising:
a third current regulator configured to regulate a current value of a current flowing through the third switch based on the first feedback signal and a fourth current regulator configured to regulate a current value of a current flowing through the fourth switch based on the second feedback signal.

9. The level-shift circuit according to claim 1, wherein
the output signal generator includes:
a latch portion having a set terminal and a reset terminal to which a high-level or low-level signal is fed according to whether the first and second switches are on and off.

10. A power supply comprising:
the level-shift circuit according to claim 1.
